(19) United States
(12) Patent Application Publication
(10) Pub. No.: US 2013/0093063 A1
(43) Pub. Date: Apr. 18, 2013

(54) BONDED SUBSTRATE AND METHOD OF MANUFACTURING THE SAME

(71) Applicant: Samsung Corning Precision Materials Co., Ltd., Gyeongsangbuk-do (KR)

(72) Inventors: Joong Won Shur, ChungCheongNam-Do (KR); Donghyun Kim, ChungCheongNam-Do (KR); Dong-Woon Kim, ChungCheongNam-Do (KR); Mikyoung Kim, ChungCheongNam-Do (KR); MinJu Kim, ChungCheongNam-Do (KR); Seung Yong Park, ChungCheongNam-Do (KR); Bohyun Lee, ChungCheongNam-Do (KR); BongHee Jang, ChungCheongNam-Do (KR)

(73) Assignee: SAMSUNG CORNING PRECISION MATERIALS CO., LTD., Gyeongsangbuk-do (KR)

(21) Appl. No.: 13/649,711

(22) Filed: Oct. 11, 2012

(30) Foreign Application Priority Data
Oct. 14, 2011 (KR) 10-2011-0105310

(51) Int. Cl. H01L 29/02; H01L 21/762

(52) U.S. Cl. 257/622; 438/456; 438/458; 257/E21.568; 257/E29.002

(57) ABSTRACT

A bonded substrate having a plurality of grooves and a method of manufacturing the same. The method includes the following steps of implanting ions into a first substrate, thereby forming an ion implantation layer, bonding the first substrate to a second substrate having a plurality of grooves in one surface thereof such that the first substrate is bonded to the one surface, and cleaving the first substrate along the ion implantation layer.

### CROSS REFERENCE TO RELATED APPLICATION

The present application claims priority from Korean Patent Application Number 10-2011-0105310 filed on Oct. 14, 2011, the entire contents of which application is incorporated herein for all purposes by this reference.

### BACKGROUND OF THE INVENTION

1. Field of the Invention

The present invention relates to a bonded substrate and a method of manufacturing the same, and more particularly, to a bonded substrate having a plurality of grooves and a method of manufacturing the same.

2. Description of Related Art

Recently, studies on compound semiconductors made of a compound of two or more elements, such as aluminum nitride (AlN), gallium nitride (GaN) or indium nitride (InN), as materials for cutting edge devices, such as light-emitting diodes (LEDs) and laser diodes (LDs), are actively underway.

In particular, since GaN can generate light in the range from ultraviolet (UV) to blue rays owing to its large transition energy bandwidth. This feature makes GaN an essential next-generation photoelectric material that is used for blue laser diodes (LDs), which are used as light sources for next-generation digital versatile discs (DVDs), white light-emitting diodes (LEDs), which are replacing the existing illumination devices, high-temperature and high-power electronic devices, and the like.

Such a compound semiconductor substrate is fabricated by bonding a grown compound semiconductor onto a base substrate.

A description will be given below of a method of manufacturing a compound semiconductor substrate as an example with respect to a GaN substrate.

FIG. 1 is a conceptual view depicting a method of manufacturing a GaN substrate of the related art.

Referring to FIG. 1, first, a sapphire substrate 11 is loaded into a reactor in order to manufacture a GaN substrate. Before the GaN substrate is grown, surface treatment can be performed by blowing a mixture gas including ammonia gas (NH₃) and hydrogen chloride (HCl) onto the sapphire substrate 11. Afterwards, a GaN substrate 21 is grown by blowing gallium chloride (GaCl) and ammonia along with a carrier gas onto the sapphire substrate 11 in the state in which the temperature inside the reactor is maintained at a high temperature of 100° C. or higher. After that, the sapphire substrate 11 on which the GaN substrate 21 is grown is cooled for approximately 8 hours, and then is etched using phosphoric acid. Finally, the sapphire substrate 11 on which the GaN substrate 21 is grown is transported into a laser cutting furnace, in which the grown GaN substrate 21 is separated from the sapphire substrate 11 by irradiating the sapphire substrate 11 with a laser beam.

The GaN substrate 21 which is separated as above is cleaved into several substrates using the layer transfer technology, thereby producing compound semiconductor substrates.

Here, the layer transfer technology refers to a technology by which the first substrate (donor substrate) into which ions are implanted is bonded to a second substrate (carrier substrate) and then the resultant structure is cleaved along an ion implantation layer of the first substrate.

FIG. 2 is a conceptual view schematically depicting a method for cleaving a substrate using the layer transfer technology of the related art.

Referring to FIG. 2, an ion implantation layer 21a is formed by implanting ions into the GaN substrate 21 which is separated as described above using an ion implanter. Afterwards, the GaN substrate 21 is abutted against a heterogeneous substrate 31, and the GaN substrate 21 and the heterogeneous substrate 31 are bonded directly to each other by warming and pressing them. Finally, the GaN substrate 21 is cleaved along the ion implantation layer 21a which is formed inside thereof by heating the bonded GaN substrate 21 and the heterogeneous substrate 31, thereby producing a bonded substrate.

In this fashion, the method for cleaving the substrate using the layer transfer technology has the process of controlling the bonding pressure and temperature of the first substrate and the second substrate and directly bonding them using a bonding device.

Here, the first substrate into which ions are implanted is subjected to warping or the like in response to a change in the crystalline structure due to ion implantation, whereas the second substrate has a plane the radius of curvature of which is indefinite. Consequently, the first and second substrates are not completely butted against to each other, but have cracks or voids owing to localized pressure, which is problematic.

The information disclosed in the Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a bonded substrate in which warping is reduced and voids are removed from the inside thereof and a method of manufacturing the same.

In an aspect of the present invention, provided is a method of manufacturing a bonded substrate that includes the following steps of: implanting ions into a first substrate, thereby forming an ion implantation layer; bonding the first substrate to a second substrate having a plurality of grooves in one surface thereof such that the first substrate is bonded to the one surface; and cleaving the first substrate along the ion implantation layer.

In an exemplary embodiment of the invention, ions that are implanted may be ions of at least one selected from the group consisting of hydrogen, helium, nitrogen, oxygen and argon.

In an exemplary embodiment of the invention, the first substrate may be made of one selected from the group consisting of gallium nitride (GaN), gallium arsenide (GaAs), indium phosphide (InP), aluminum nitride (AlN), aluminum gallium nitride (AlGaN) and indium gallium nitride (InGaN).

In an exemplary embodiment of the invention, the grooves are configured to extend from a first periphery of the second substrate to a second periphery of the second substrate opposite to the first periphery.

In an exemplary embodiment of the invention, the grooves formed in the second substrate may be a pattern selected from the group consisting of a straight-line pattern, a grid pattern and a honeycomb pattern.

In an exemplary embodiment of the invention, the step of bonding the first substrate to the second substrate may be carried out by bonding the first substrate to the second substrate via surface activated bonding or direct bonding.

In another aspect of the present invention, provided is a bonded substrate that includes a first thin substrate; and a second substrate bonded with the first thin substrate, the second substrate having a plurality of grooves in a surface thereof which is bonded to the first thin substrate.

In an exemplary embodiment of the invention, the grooves formed in the second substrate may be a pattern selected from the group consisting of a straight-line pattern, a grid pattern and a honeycomb pattern.

According to embodiments of the invention, it is possible to manufacture a bonded substrate in which warping is reduced.

In addition, it is possible to manufacture a bonded substrate in which the quality of bonding between the first thin substrate and the second substrate is improved since the inner voids between the first thin substrate and the second substrate are removed.

The methods and apparatuses of the present invention have other features and advantages which will be apparent from, or are set forth in more detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a conceptual view depicting a method of manufacturing a GaN substrate of the related art;

FIG. 2 is a conceptual view schematically depicting a method for cleaving a substrate using the layer transfer technology of the related art;

FIG. 3 is a schematic flowchart depicting a method of manufacturing a bonded substrate according to an embodiment of the invention;

FIG. 4 is a picture depicting a bonding surface after a GaN substrate is bonded to a Si substrate in which no grooves are formed;

FIG. 5 shows pictures depicting bonding surfaces after a GaN substrate is bonded to Si substrates in which a line pattern, a grid pattern and a honeycomb pattern are formed respectively;

FIG. 6 is a picture depicting a bonding surface of a bonded substrate in which a GaN substrate is cleaved along an ion implantation layer after the GaN substrate is bonded to a Si substrate in which no grooves are formed;

FIG. 7 shows pictures depicting bonding surfaces of bonded substrates in which a GaN substrate is cleaved along an ion implantation layer after the GaN substrate is bonded to Si substrates in which a line pattern, a grid pattern and a honeycomb pattern are formed respectively; and

FIG. 8 is a schematic cross-sectional view of a bonded substrate according to an embodiment of the invention.

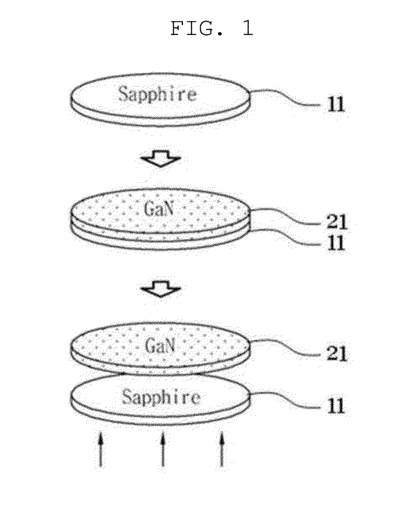

### DETAILED DESCRIPTION OF THE INVENTION

Reference will now be made in detail to a bonded substrate and a method of manufacturing the same according to the present invention, examples of which are illustrated in the accompanying drawings.

In the following description of the present invention, detailed descriptions of known functions and components incorporated herein will be omitted when they may make the subject matter of the present invention unclear.

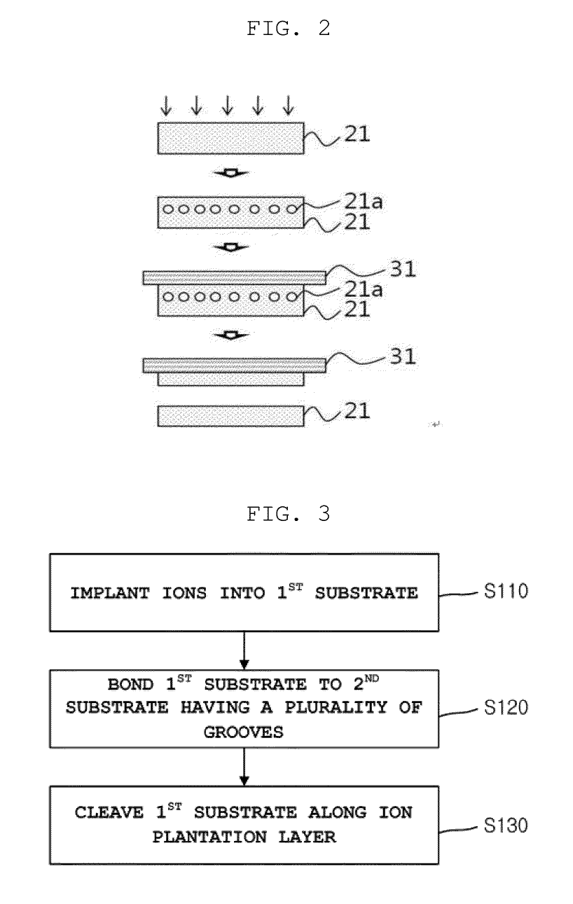

FIG. 3 is a schematic flowchart depicting a method of manufacturing a bonded substrate according to an embodiment of the invention.

Referring to FIG. 3, the method of manufacturing a bonded substrate of this embodiment includes an ion implantation step, a bonding step and a cleaving step.

In order to manufacture a bonded substrate, first, at S110, an ion implantation layer is formed by implanting ions into a first substrate.

The ion implantation layer may be formed by implanting ions into the first substrate using an ion implanter.

Here, ions which are implanted may be ions of one selected from among hydrogen, helium, nitrogen, oxygen, argon and mixtures thereof.

The range of energy that is necessary for ion implantation will be determined depending on the type of substrates to which ions are to be implanted, the type of ions which are to be implanted, the depth to which ions are to be implanted, and the like. The depth to which ions are implanted will be determined depending on the thickness of a substrate which is intended to be manufactured.

The first substrate may be a compound semiconductor substrate which is made of one selected from among gallium nitride (GaN), gallium arsenide (GaAs), indium phosphide (InP), aluminum nitride (AlN), aluminum gallium nitride (AlGaN), indium gallium nitride (InGaN) and the like.

When ions are implanted into the first substrate, a damage layer owing to the ion implantation is formed in the first substrate, and the crystalline lattice structure of the first substrate or the like is changed. Consequently, the first substrate is warped by stress such that it has a convex shape toward the ion implanted surface.

That is, when ions are implanted, the surface area of the ion implanted surface increases so that the first substrate is warped in a convex shape toward the ion implanted surface.

At S120, the first substrate which is warped in a convex shape toward the ion implanted surface as described above is bonded to a second substrate having a plurality of grooves in one surface thereof. The second substrate may be a substrate of Si, Al₂O₃, GaAs, SiC or the like.

In the bonding step, the ion implanted surface of the first substrate will be bonded to the surface of the second substrate in which the plurality of grooves is formed.

The grooves formed in the second substrate may be formed by dry or wet etching, and may have one pattern selected from among a line pattern, a grid pattern and a honeycomb pattern. However, the grooves may have a variety of shapes without being limited thereto.

The bonding between the first substrate and the second substrate may be carried out by a surface activated bonding which activates the bonding surface by exposing it to plasma so that the substrate and the second substrate are bonded together at a temperature ranging from room temperature to 400° C.

Alternatively, the bonding may be carried out by seating the first substrate on the surface of the second substrate in which the grooves are formed and pressing the substrates in a high-temperature atmosphere having a temperature ranging from 300° C. to 400° C. After the bonding, only a first thin substrate which is cleaved from the first substrate remains bonded to the second substrate.

In this fashion, the first substrate which is convexly warped is bonded to the second substrate in which the plurality of grooves is formed. Consequently, localized pressure which is created by the warped first substrate during pressing can be alleviated due to deformation of the second substrate, thereby reducing warping in the bonded substrate.

In addition, the grooves in the second substrate can be formed such that they extend from one periphery to the other periphery of the second substrate. It is preferred that the two peripheries face each other.

In the related art, gases such as air are trapped inside the bonding surface since a flat substrate without grooves is bonded to the warped first substrate. However, in the present invention, the gases can be exhausted outward through the grooves in the second substrate, thereby removing voids inside the bonding surface and the quality of bonding.

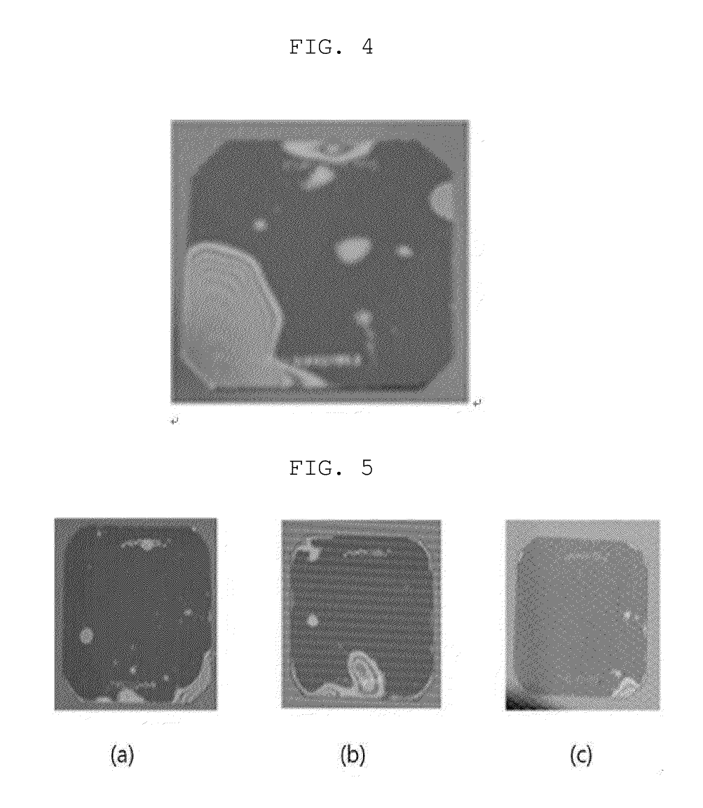

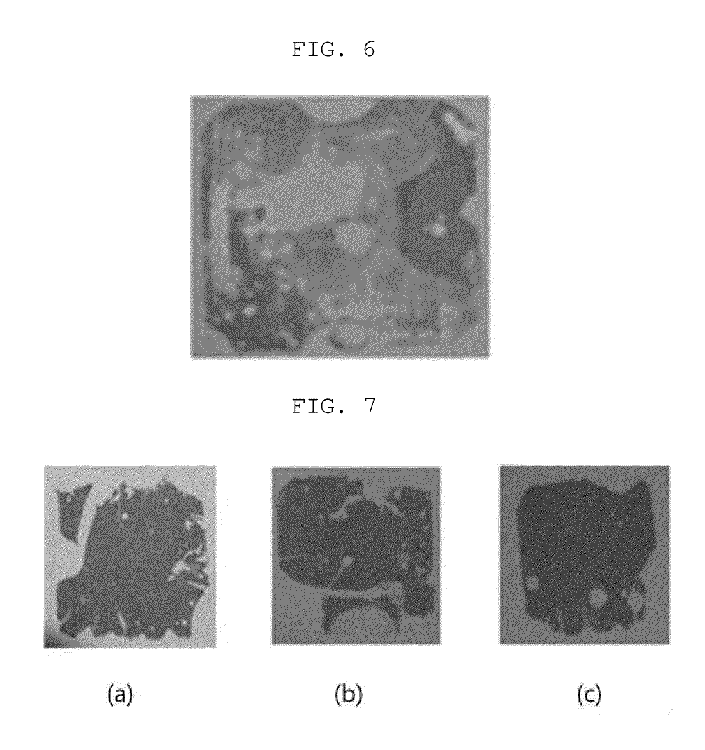

FIG. 4 is a picture depicting a bonding surface after a GaN substrate is bonded to a Si substrate in which no grooves are formed, and FIG. 5 shows pictures depicting bonding surfaces after a GaN substrate is bonded to Si substrates in which a line pattern, a grid pattern and a honeycomb pattern are formed respectively.

Comparing FIG. 4 and FIG. 5, it can be appreciated that the area of a surface of the Si substrate (the white area on the pictures) which is not bonded to the GaN substrate is wider when no grooves are formed than when grooves are formed. That is, it can be appreciated that the quality of bonding is improved when the grooves are formed in the Si substrate.

Afterwards, at S130, the first substrate is cleaved along the ion implantation layer, thereby producing a bonded substrate.

The step of cleaving the first substrate can be carried out by heating the first and second substrates which are bonded together so that the ion implantation layer inside the first substrate is transformed into a gas layer, which in turn expands.

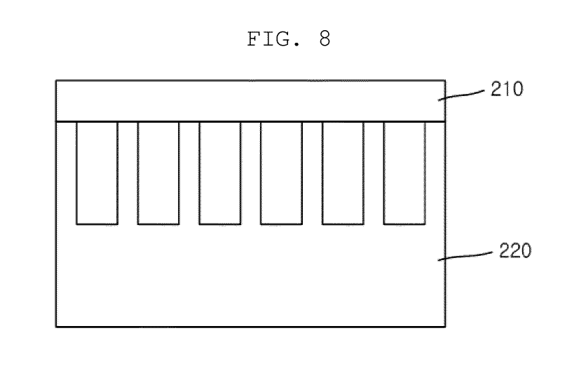

FIG. 6 is a picture depicting a bonding surface of a bonded substrate in which a GaN substrate is cleaved along an ion implantation layer after the GaN substrate is bonded to a Si substrate in which no grooves are formed, and FIG. 7 shows pictures depicting bonding surfaces of bonded substrates in which a GaN substrate is cleaved along an ion implantation layer after the GaN substrate is bonded to Si substrates in which a line pattern, a grid pattern and a honeycomb pattern are formed respectively.

Comparing FIG. 6 and FIG. 7, it can be appreciated that the quality of bonding of the bonded substrate in which the Si substrate has the grooves is improved.

FIG. 8 is a schematic cross-sectional view of a bonded substrate according to an embodiment of the invention.

Referring to FIG. 8, the bonded substrate of the invention may include a first thin substrate 210 and a second substrate 220 having a plurality of grooves formed in one surface thereof which is bonded to the first substrate.

The bonded substrate can be used for an LED substrate, a semiconductor substrate, and the like.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A method of manufacturing a bonded substrate comprising:
implanting ions into a first substrate, thereby forming an ion implantation layer;
bonding the first substrate to a second substrate having a plurality of grooves in one surface thereof such that the first substrate is bonded to the one surface; and
cleaving the first substrate along the ion implantation layer.

2. The method of claim 1, wherein the first substrate comprises one selected from the group consisting of gallium nitride (GaN), gallium arsenide (GaAs), indium phosphide (InP), aluminum nitride (AlN), aluminum gallium nitride (AlGaN) and indium gallium nitride (InGaN).

3. The method of claim 1, wherein the ions that are implanted comprise ions of at least one selected from the group consisting of hydrogen, helium, nitrogen, oxygen and argon.

4. The method of claim 1, wherein the grooves are configured to extend from a first periphery of the second substrate to a second periphery of the second substrate opposite to the first periphery.

5. The method of claim 1, wherein the grooves formed in the second substrate comprise a pattern selected from the group consisting of a straight-line pattern, a grid pattern and a honeycomb pattern.

6. The method of claim 1, wherein bonding the first substrate to the second substrate comprises bonding the first substrate to the second substrate via surface activated bonding or direct bonding.

7. A bonded substrate comprising:
a first thin substrate; and
a second substrate bonded with the first thin substrate, the second substrate having a plurality of grooves in a surface thereof which is bonded to the first thin substrate.

8. The bonded substrate of claim 7, wherein the grooves formed in the second substrate comprise a pattern selected from the group consisting of a straight-line pattern, a grid pattern and a honeycomb pattern.
